(19) United States
(12) Patent Application Publication
(10) Pub. No.: US 2016/0118629 A1
(43) Pub. Date: Apr. 28, 2016

(54) ORGANIC LIGHT EMITTING DISPLAY DEVICE AND MANUFACTURING METHOD THEREOF

(71) Applicant: EverDisplay Optronics (Shanghai) Limited, Shanghai City (CN)

(72) Inventors: Huanhsun HSIEH, Shanghai City (CN); Chengpei HUANG, Shanghai City (CN); Chiate CHO, Shanghai City (CN)

(21) Appl. No.: 14/879,228

(22) Filed: Oct. 9, 2015

(30) Foreign Application Priority Data
Oct. 15, 2014 (CN) 201410545120.X

(51) Int. Cl. H01L 51/52; H01L 27/32; H01L 51/00; H01L 51/56; H01L 51/50

(52) U.S. Cl. CPC H01L 51/5293; H01L 51/56; H01L 51/5056; H01L 51/0096; H01L 51/524; H01L 27/3244; H01L 51/0035; H01L 51/004; H01L 51/5072; H01L 51/5012; H01L 2251/303; H01L 2251/305

(57) ABSTRACT

An organic light emitting display device and its manufacturing method are provided. The manufacturing method includes: providing a substrate; forming a thin film transistor unit on one side of the substrate; forming an organic light emitting diode unit at a side of the thin film transistor opposite to the substrate; providing a cover plate; attaching a polarizer on the cover plate; and packaging the cover plate having the attached polarizer onto the organic light emitting diode unit, wherein the polarizer is interposed between the organic light emitting diode unit and the cover plate.

This application is based upon and claims priority to Chinese Patent Application No. 201410545120.X, filed on Oct. 15, 2014, the entire contents of which are incorporated herein by reference.

### TECHNICAL FIELD

The present disclosure relates to a panel display, particularly, to an organic light emitting display and a manufacturing method of the same.

### BACKGROUND

An organic light emitting display device has a property of self-emitting, and uses a very thin organic material coating layer and a glass substrate, wherein the organic material emits light when current flows therethrough. The screen of the organic light emitting display device may have a large view angle, and may significantly save electrical power, thereby the organic light emitting display device has a plurality of incomparable advantages over an LCD display device.

An organic light emitting display device may be classified as a passive matrix type and an active matrix type. In the passive matrix type, pixels are arranged in matrix at the intersections of scanning lines and signal lines, while in the active type, each pixel is controlled by a thin film transistor operating as a switch.

In a passive matrix organic light emitting display device, each pixel is driven by sequentially driving scanning lines during a period of time, while in an active matrix organic light emitting device, each pixel is driven by a storage capacitor. Accordingly, same luminance may be obtained using a low current in the active matrix organic light emitting display device, so that the active matrix organic light emitting display device is advantageous over the passive matrix organic light emitting display device in its low power consuming, high resolution and large size.

### SUMMARY

The present disclosure provides a method of manufacturing an organic light emitting display device, including: providing a substrate; forming a thin film transistor unit on one side of the substrate; forming an organic light emitting diode unit at a side of the thin film transistor opposite to the substrate; providing a cover plate; attaching a polarizer on the cover plate; and packaging the cover plate having the attached polarizer onto the organic light emitting diode unit, wherein the polarizer is interposed between the organic light emitting diode unit and the cover plate.

Preferably, the polarizer includes a linear polarizing film and a phase retardation plate, and the phase retardation plate is interposed between the linear polarizing film and the organic light emitting diode unit.

Preferably, the phase retardation plate is a quarter wavelength plate, and an angle between the optic axis of the phase retardation plate and the polarizing axis of the linear polarizing film is about 45 degrees.

Preferably, the linear polarizing film is formed of polyvinyl alcohol based material.

Preferably, the substrate is made of one of the following materials: polyethylene terephthalate (PET); polyisoprene (PI); polyethylene naphthalate (PEN); polyethersulfone (PES); and polycarbonate (PC).

Preferably, the organic light emitting diode unit includes: a hole transporting layer formed on the thin film transistor unit; an organic light emitting layer formed on the hole transporting layer; and an electron transporting layer formed on the organic light emitting layer.

Preferably, the cover plate is a glass cover plate.

According to another aspect of the present disclosure, it further provides an organic light emitting display device, including: a substrate; a thin film transistor unit formed on one side of the substrate; an organic light emitting diode unit formed on a side of the thin film transistor unit opposite to the substrate; a cover plate; and a polarizer attached on the cover plate, wherein the cover plate having the attached polarizer is packaged onto the organic light emitting diode unit, and the polarizer is interposed between the organic light emitting diode unit and the cover plate.

Preferably, the polarizer includes a linear polarizing film and a phase retardation plate, and the phase retardation plate is interposed between the linear polarizing film and the organic light emitting diode unit.

Preferably, a linear polarized light passed through the linear polarizing film is circularly polarized after passing through the phase retardation plate.

Preferably, the phase retardation plate is a quarter wavelength plate, and an angle between the optic axis of the phase retardation plate and the polarizing axis of the linear polarizing film is about 45 degrees.

Preferably, the linear polarizing film is formed of polyvinyl alcohol based material.

Preferably, the substrate is made of one of the following materials: polyethylene terephthalate (PET); polyisoprene (P1); polyethylene naphthalate (PEN); polyethersulfone (PES); and polycarbonate (PC).

Preferably, the organic light emitting diode includes: a hole transporting layer formed on the thin film transistor unit; an organic light emitting layer formed on the hole transporting layer; and an electron transporting layer formed on the organic light emitting layer.

Preferably, the cover plate is a glass cover plate.

### BRIEF DESCRIPTION OF THE DRAWINGS

The above and other features and advantages of the present disclosure will become more apparent by describing its example implements in detail with reference to the accompanying drawings.

FIG. 1 illustrates a side cross sectional view of a passive matrix organic light emitting display device in the prior art.

FIG. 2 illustrates a side cross sectional view of an active matrix organic light emitting display device in the prior art.

FIG. 3 illustrates a driving circuit diagram of a pixel of an organic light emitting display device provided by the present disclosure.

FIG. 4 illustrates a side cross section view of an organic light emitting display device provided by the present disclosure.

FIG. 5 illustrates a flow chart of a method of manufacturing an organic light emitting display device provided by the present disclosure.

FIGS. 6A, 6B, 6C, 6D, 6E and 6F are side cross sectional views illustrating variations of an organic light emitting display device provided by the present disclosure during its manufacturing processes.

### DETAILED DESCRIPTION

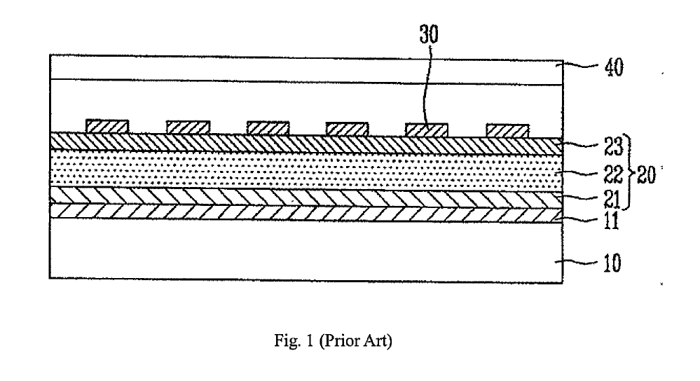

FIG. 1 is a schematic cross section view of an example of a conventional passive matrix organic light emitting display device.

Anode electrode 11 is formed on an insulating substrate 10, and a thin organic layer 20 is formed on the anode electrode 11. The thin organic layer 20 is formed with a stacked structure of a hole transporting layer 21, an organic light emitting layer 22 and an electron transporting layer 23, and the thin organic layer 20 may further include a hole injection layer and an electron injection layer. Further, at the top of the thin organic layer 20, a cathode electrode 30 is formed across the anode electrode 11. The above organic light emitting display device is sealed with a sealing substrate 40.

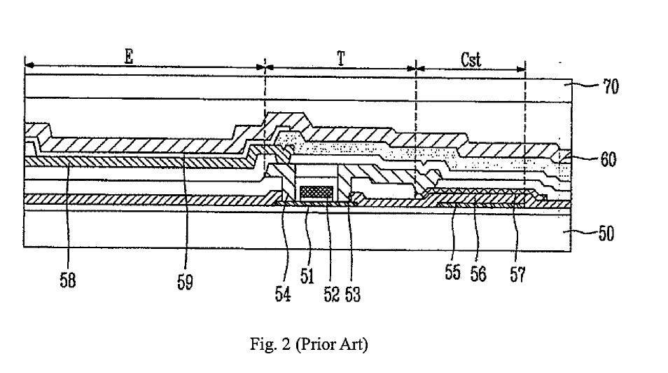

FIG. 2 is a schematic cross section view of an example of a conventional active matrix organic light emitting display device.

A thin film transistor T including a semiconductor layer 51, a gate electrode 52, a source electrode 53 and a drain electrode 54 is formed on an insulating substrate 50. The source electrode 53 of the thin film transistor T is connected with a storage capacitor C_{ST}, wherein the storage capacitor C_{ST} includes a stack structure of an electrode 55, a dielectric 56 and an electrode 57. The drain electrode 54 is connected to a light emitting element E, wherein the light emitting element E includes a stack structure of an anode electrode 58, an organic layer 59 and a cathode electrode 60. The above organic light emitting display device is sealed by with sealing substrate 70.

In the organic light emitting display device as mentioned above, when a predetermined voltage is applied across the anode electrode and the cathode, holes injected through the anode and electrons injected through the cathode are recombined in the light emitting layer, thereby emitting light using an energy difference occurred during said process.

In order to facilitate electron injection and improve the light emitting efficiency, a metal, such as magnesium (Mg), magnesium aluminum alloy, aluminum (Al), lithium aluminum alloy, and calcium (Ca), is usually used to form the cathode electrode in the organic light emitting display device. However, when light is incident from an outside of the organic light emitting display device, a portion of the incident light is reflected on the metal cathode since the metal cathode has a very high surface reflectivity. Such an inner reflection may cause problems regarding visibility deterioration of contrast ratio of the organic light emitting display device.

In order to reduce the reflection of light from the external light source, it has been proposed that a circular polarizer of a quarter wavelength phase plate and a linear polarizer are used on a surface of a plate on the path of the emitted light, so as to compensate the deteriorated contrast ratio of the organic light emitting display device.

In a case in which a polarizer transferring light having a particular polarization direction (e.g., a horizontal wave only) is used, the horizontal wave passed through the linear polarizer is reflected by the internal metal electrode, and then phase changed by the quarter wavelength phase plate, thereby the horizontal wave no longer passes through the polarizer, and thus may be eliminated. Accordingly, a phase difference is created using the quarter wavelength phase plate; thereby the incident light cannot be reflected, and thus leading to reduction of the reflection of external light.

In a current available method of manufacturing the organic light emitting display device that uses a polarizer to compensate for its deteriorated contrast ratio, the polarizer is typically attached to the light emitting element of the organic light emitting display device using adhesive. With such a manufacturing method, the thickness of the adhesive and the polarizer may reach to 0.15 to 0.3 millimeter (mm).

Example implements are described more fully with reference to the accompanying drawings. However, the example implements can be implemented in many ways without being explained as being limited to the implements set forth therein; instead, these implements are provided such that the present disclosure will be through and complete, and will fully convey the concept of the example implements to those skilled in the art. In the drawings, thicknesses of regions and layers are exaggerated for clarity. Like reference numerals represent same or like structures in the drawings, and thus their detailed description will be omitted.

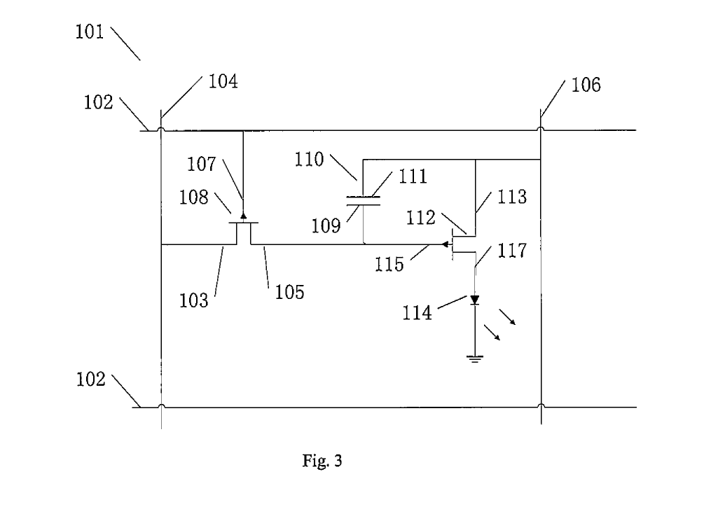

FIG. 3 illustrates a driving circuit diagram of one pixel of an organic light emitting display device provided by the present disclosure. In the organic light emitting display device, each pixel 101 includes a thin film transistor unit and an organic light emitting diode unit 114. The thin film transistor unit includes a switch thin film transistor unit 108, a driving thin film transistor unit 112 and a capacitor 110. In addition, the organic light emitting display device further includes a plurality of scanning lines 102 extending in one direction and a plurality of data lines 104 and common power lines 106 crossing and insulated from the gate lines 102, respectively. Wherein, one pixel may be defined by the area surrounded by two adjacent gate lines 102, a data line 104 and a common power line 106.

The organic light emitting diode unit 114 includes a pixel electrode, an organic emission layer and a common electrode formed on the organic emission layer. Wherein, the pixel electrode is used as an anode of a hole injection electrode, and the common electrode is used as a cathode of an electron injection electrode. In a variation, according to the method of driving the organic light emitting display device, the pixel electrode may be the cathode, and the common electrode may be the anode. Holes and electrons are injected to the organic emission layer respectively, forming excitons. When the excitons changes from its excited state to its ground state, light is emitted.

The switch thin film transistor 108 includes a switch semiconductor layer, a switch gate electrode 107, a switch source electrode 103 and a switch drain electrode 105. The driving thin film transistor 112 includes a driving semiconductor layer, a driving gate electrode 115, a driving source electrode 113 and a driving drain electrode 117.

The capacitor 110 includes a first sustain electrode 109 and a second sustain electrode 111, and an interlayer insulating layer provided between the first sustain electrode 109 and the second sustain electrode 111.

The switch thin film transistor 108 is used as a switch for selecting the emitting pixel. The switch gate electrode 107 is connected to the gate line 102. The switch 103 is connected to the data line 104. The switch drain 105 is arranged a certain distance away from the switch source electrode 103, and the switch drain electrode 105 is connected to the first sustain electrode 109.

The driving thin film transistor 112 applies driving power to the pixel electrode, so that the organic emission layer of the organic light emitting diode unit 114 of the selected pixel emits light. The driving gate electrode 115 is connected to the first sustain electrode. The driving source electrode 113 and the second sustain electrode 111 are connected to the common power line 106, respectively. The driving drain electrode 117 is connected to the pixel electrode of the organic light emitting diode unit 114 via a contact hole.

With the structure mentioned above, switch thin film transistor 108 is driven by a gate voltage applied to the gate electrode 102, thereby transporting the data voltage applied to the data line 104 to the driving thin film transistor 112. A voltage difference between the common voltage transported from the common power line 106 to the driving thin film transistor 112 and the data voltage transported via the switch thin film transistor 108 is stored in the capacitor 110, and a current corresponding to the voltage stored in the capacitor 110 flows to the organic light emitting diode unit 114 via the driving thin film transistor 112. Thus, the organic light emitting diode unit 114 emits light.

The organic light emitting display device further includes a substrate, a cover plate and a polarizer (all not illustrated in the drawing). The thin film transistor unit and the organic light emitting diode unit 114 are formed on the substrate. The polarizer covers one side of the cover plate, and the side of the cover plate covered with the polarizer faces the side of the substrate formed with thin film transistor unit and the organic light emitting diode unit 114, so as to reduce the thickness of the organic light emitting display device packaged.

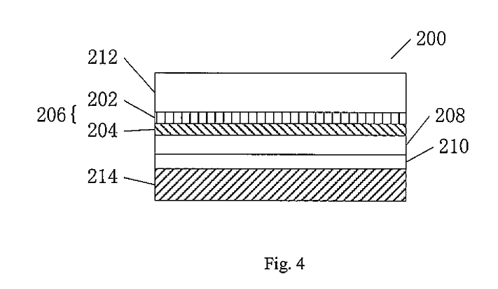

FIG. 4 is a side cross section view of the organic light emitting display device provided by the present disclosure. The organic light emitting display device 200 includes a substrate 214, a thin film transistor unit 210, an organic light emitting diode unit 208, a polarizer 206 and a cover plate 212.

The substrate 214 is formed of an insulating material such as glass, ceramic or plastic. However, the embodiment of the present disclosure is limited thereto. Therefore, the substrate 214 may be a conductive metal substrate made of stainless steel and the like.

The circuit structure of the thin film transistor unit 210, as shown in FIG. 3, includes the switch thin film transistor 118, the driving thin film transistor 112 and the capacitor 110. The switch thin film transistor includes the switch semiconductor layer, the switch gate electrode 107, the switch source electrode 103 and the switch drain electrode 105. The driving thin film transistor 112 includes the driving semiconductor layer, the driving gate electrode 115, the driving source electrode 113 and the driving drain electrode 117. The capacitor includes the first sustain electrode 109 and the second sustain electrode 111, and the interlayer insulating layer between the first sustain electrode and the second electrode.

The driving thin film transistor is formed according to the method as follows.

A driving semiconductor layer of the driving thin film transistor of the thin film transistor unit 210 (not illustrated in the drawing) is formed on the substrate 214. Preferably, the driving semiconductor layer is formed of poly silicon. In addition, the driving semiconductor includes an undoped channel region, and a source region and a drain region doped with a p+ impurity at both sides of the channel region. In this case, the doped ion material is a p type impurity, such as boron (B). B₂H₆ is usually used as the doped ion material. The impurity is change according to the type of the thin film transistor.

Preferably, a thin film transistor having a PMOS structure with a p type impurity is used as the driving thin film transistor. However, those skilled in the art would appreciate that the present disclosure is not limited thereto. Therefore, a thin film transistor having an NMOS structure or a thin film transistor having a CMOS structure may be used as the driving thin film transistor.

A gate insulating layer made of a silicon nitride (SiNₓ) or a silicon oxide (SiO₂) is formed on the driving semiconductor layer. A gate wiring including a gate electrode is formed on the gate insulating layer. The gate wiring further includes a gate line, a first sustain electrode and other wiring. In addition, the driving gate electrode is formed to overlap at least a part of the driving semiconductor layer; in particular, the driving gate electrode overlaps the channel region.

An interlayer insulating layer covering the driving gate electrode is formed on the gate insulating layer. The gate insulating layer and the interlayer insulating layer share via holes exposing the source region and the drain region of the driving semiconductor layer. Similar to the gate insulating layer, in this embodiment, the interlayer insulating layer is made of a ceramic based material (e.g., silicon nitride (SiNₓ) or silicon oxide (SiO₂)).

A data wiring including the driving source electrode and the driving drain electrode is formed on the interlayer insulating layer. The data wiring further includes a data line, a common power line, a second sustain electrode and other wirings. In addition, the driving source electrode and the driving drain electrode are connected to the source region and drain region of the driving semiconductor layer via the via holes, respectively.

The structure of the driving thin film transistor is not limited to the above embodiment, and it can be modified in different ways according to the known structures understandable to those ordinary skilled in the art.

In addition, the formation of the switch thin film transistor is similar to that of the driving thin film transistor, and it is not repeated herein. The switch thin film transistor may be a polycrystalline thin film transistor or an amorphous thin film transistor including an amorphous silicon layer.

The organic light emitting display unit 208 is formed according to the method as follows.

A pixel electrode of the organic light emitting display unit 208 is formed on the thin film transistor unit 210. The pixel electrode is connected to the driving drain electrode. In addition, the pixel is configured to correspond to an opening of a pixel defining layer. The pixel defining layer may be made of silica based inorganic material or resin (e.g., polyacrylate ester resin or polyimide).

A organic emission layer is formed on the pixel electrode and in the opening of the pixel defining layer, and a common electrode is formed on the pixel defining layer and the organic emission layer.

One or both of the pixel electrode and the common electrode may be formed on transparent conductive material, wherein one of which may be formed of transflective conductive material or reflective conductive material. According to the choices of the material of the pixel electrode and the common electrode, the organic light emitting display device 200 may be classified into a top emission type, a bottom emission type and a dual emission type.

As the transparent conductive material, various embodiments use indium tin oxide (ITO), indium zinc oxide (IZO), zinc oxide (ZnO), or indium oxide (In₂O₃). As the reflective material, various embodiments use lithium (Li), calcium (Ca), lithium fluoride/calcium (LiF/Ca), lithium fluoride/aluminum (LiF/Al), aluminum (Al), silver (Ag), magnesium (Mg) or gold (Au).

In some embodiments, the organic emission layer is made of low molecular weight material or high molecular weight material. Such a organic emission layer may be formed of a multilayer structure including a hole injection layer, a hole transporting layer, a emission layer, an electron transporting layer and an electron injection layer. That is, the hole injection layer is formed on the pixel electrode (i.e., the positive electrode), and the hole transporting layer, the emission layer, the electron transporting layer and the electron injection layer are sequentially stacked on the hole injection layer.

The polarizer 206 includes a linear polarizing film 202 and a phase retardation plate 204. Wherein the phase retardation plate 204 is a quarter wavelength plate, and a crossing angle between the optic axis of the phase retardation plate 204 and the polarizing axis of the linear polarizing film 202 is about 45 degrees. The linear polarizing film 202 is formed of polyvinyl alcohol based material.

The thin film transistor unit 210 is formed on one side of the substrate 214. The organic light emitting diode unit 208 is formed at a side of the thin film transistor unit 210 opposite to the substrate 214 (that is, the thin film transistor unit 210 is positioned between the organic light emitting diode unit 208 and the substrate 214). The polarizer 206 is positioned between the organic light emitting diode unit 208 and the cover plate 212. Wherein, the phase retardation plate 204 is interposed between the linear polarizing layer 202 and the organic light emitting diode unit 208.

In a modified embodiment, the organic light emitting display device 200 further includes a planarization layer. The planarization layer covers the thin film transistor unit 210. The planarization layer removes steps and performs planarization, thereby increasing the light emitting efficiency of the organic light emitting display device 200. In addition, the planarization layer includes a contact hole, and the drain electrode part of the thin film transistor unit 210 is exposed through the contact hole.

The planarization layer is made of polyacrylate resin, epoxy resin, phenol-formaldehyde resin, polyamide resin, polyimide resin, unsaturated polyester resin, unsaturated polyester resin, polypheylene ether, polyphenylene sulfide resin and/or benzocyclobutene (BCB).

In a modified embodiment, the organic light emitting display device 200 further includes a buffer layer (not illustrated in the figure). The buffer layer is formed on the substrate 214. The buffer layer prevents the impurity from penetrating the substrate 214, and planarizes the surface of the substrate 214. The buffer layer is made of one or more different materials performing such a function. For example, a silicon nitride (SiNₓ) layer, a silicon oxide (SiO₂) layer and/or a silicon oxynitride (SiOₓN_{y}) layer may be used as the buffer layer. However, the buffer layer is not always necessary, according to the type of the substrate 214 and process conditions, the buffer layer may be omitted.

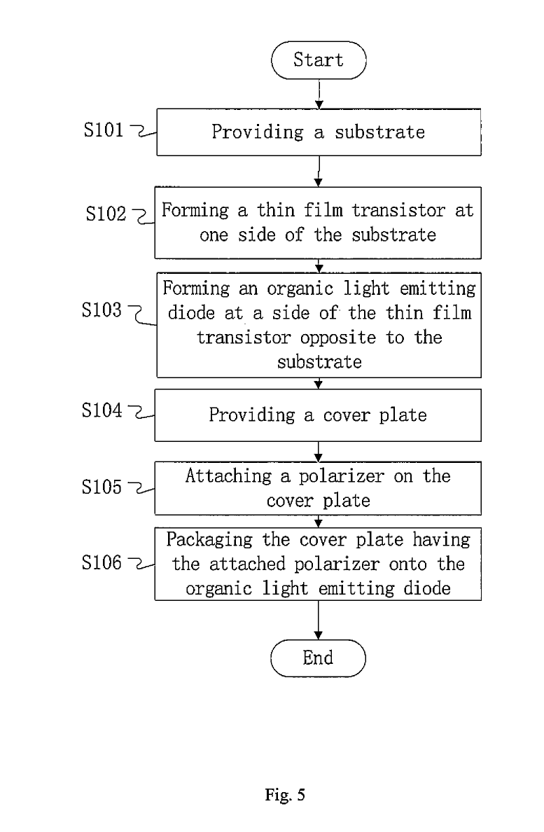

FIG. 5 is a flow chart of the manufacturing method of the organic light emitting display device provided by the present disclosure. Particularly, six steps are illustrated in this figure.

In step S101, a substrate is provided. Wherein, the substrate is formed of insulating material such as glass, ceramic or plastic. However, embodiments of the present disclosure are not limited thereto. Therefore, the substrate may be a conductive metal substrate formed of stainless steel and the like.

In step S102, a thin film transistor unit is formed on one side of the substrate. Wherein, the thin film transistor unit includes a switch thin film transistor, a driving thin film transistor and a capacitor. The switch thin film transistor includes a switch semiconductor layer, a switch gate electrode, a switch source electrode and a switch drain electrode. The driving electrode includes a driving semiconductor layer, a driving gate electrode, a driving source electrode and a driving drain electrode. The capacitor includes a first sustain electrode and a second sustain electrode, and an interlayer insulating layer interposed between the first and second sustain electrodes. 100711 In step S103, an organic light emitting diode unit is formed on a side of the thin film transistor unit opposite to the substrate. A pixel electrode of the organic light emitting display unit is formed on the thin film transistor unit. The pixel electrode is connected to the drain electrode. In addition, the pixel electrode is arranged corresponding to an opening of the pixel defining layer. The pixel defining layer may be made of silica based inorganic material or resin (for example, polyacrylate ester resin or polyimide). An organic emission layer is formed on the pixel electrode and in the opening of the pixel defining layer, and a common electrode is formed on the pixel defining layer and the organic emission layer. One or both of the pixel electrode and the commonly electrode may be made of transparent conductive material, wherein one of which may be formed of transflective conductive material or reflective conductive material. According to the choices of the material of the pixel electrode and the common electrode, the organic light emitting display device may be classified into a top emission type, a bottom emission type and a dual emission type. As the transparent conductive material, various embodiments use indium tin oxide (ITO), indium zinc oxide (IZO), zinc oxide (ZnO), or indium oxide (In₂O₃). As the reflective material, various embodiments use lithium (Li), calcium (Ca), lithium fluoride/calcium (LiF/Ca), lithium fluoride/aluminum (LiF/Al), aluminum (Al), silver (Ag), magnesium (Mg) or gold (Au).

In some embodiments, the organic emission layer is made of low molecular weight material or high molecular weight material. Such an organic emission layer may be formed of a multilayer structure including a hole injection layer, a hole transporting layer, a emission layer, an electron transporting layer and an electron injection layer. That is, the hole injection layer is formed on the pixel electrode (i.e., the positive electrode), and the hole transporting layer, the emission layer, the electron transporting layer and the electron injection layer are sequentially stacked on the hole injection layer.

In step S104, a cover plate is provided.

In step S 105, a polarizer is attached on the cover plate. The polarizer includes a linear polarizing layer and a phase retardation plate. Wherein, the phase retardation plate is a quarter wavelength plate, and a crossing angle between the optic axis of the phase retardation plate and the polarizing axis of the linear polarizing film is about 45 degrees. The linear polarizing film is formed of polyvinyl alcohol based material. In step S106, the cover plate attached with the polarizer is sealed onto the organic light emitting diode unit, and the polarizer is positioned between the organic light emitting diode unit and the cover plate. The phase retardation plate is interposed between the linear polarizing film and the organic light emitting diode unit.

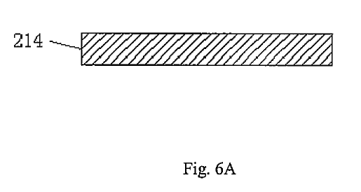

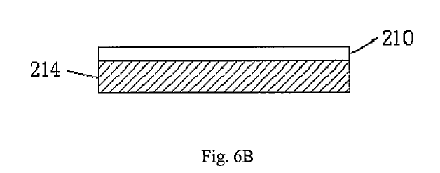

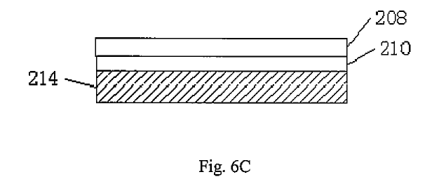

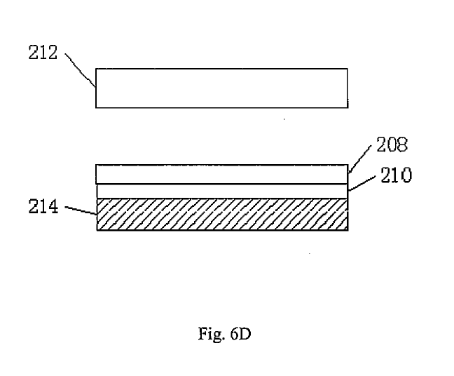

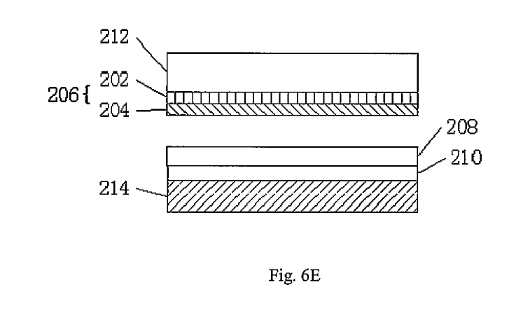

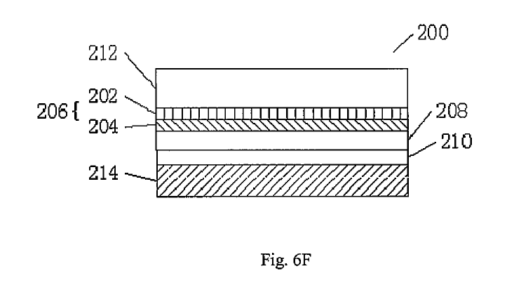

FIGS. 6A, 6B, 6C, 6D, 6E and 6F illustrates side cross sectional views illustrating variations of an organic light emitting display device during its manufacturing processes.

FIG. 6A corresponds to the step S101 of FIG. 5, and a substrate 214 is provided. The substrate 214 is formed of insulating material such as glass, ceramic or plastic. However, embodiments of the present disclosure are not limited thereto. Therefore, the substrate 214 may be a conductive metal substrate formed of stainless steel and the like.

FIG. 6B corresponds to the step S102 of FIG. 5, and a thin film transistor unit 210 is formed on one side of the substrate 214 as shown in FIG. 3. The thin film transistor unit 210 includes a switch thin film transistor 118, a driving thin film transistor 112 and a capacitor 110. The switch thin film transistor includes a switch semiconductor layer, a switch gate electrode 107, a switch source electrode 103 and a switch drain electrode 105. The driving electrode includes a driving semiconductor layer, a driving gate electrode 115, a driving source electrode 113 and a driving drain electrode 117. The capacitor includes a first sustain electrode 109 and a second sustain electrode 111, and an interlayer insulating layer interposed between the first and second sustain electrodes.

FIG. 6C corresponds to the step S103 of FIG. 5, and an organic light emitting diode unit 208 is formed on a side of the thin film transistor unit 210 opposite to the substrate 214. Wherein, the organic light emitting display unit 208 is formed according to the method as follows: a pixel electrode of the organic light emitting display unit 208 is formed on the thin film transistor unit 210. The pixel electrode is connected to the drain electrode. In addition, the pixel electrode is arranged corresponding to an opening of a pixel defining layer. The pixel defining layer may be made of silica based inorganic material or resin (e.g., polyacrylate ester resin or polyimide).

An organic emission layer is formed on the pixel electrode and in the opening of the pixel defining layer, and a common electrode is formed on the pixel defining layer and the organic emission layer.

One or both of the pixel electrode and the commonly electrode may be made of transparent conductive material, wherein one of which may be formed of transflective conductive material or reflective conductive material. According to the choices of the material of the pixel electrode and the common electrode, the organic light emitting display device 200 may be classified into a top emission type, a bottom emission type and a dual emission type.

As the transparent conductive material, various embodiments use indium tin oxide (ITO), indium zinc oxide (IZO), zinc oxide (ZnO), or indium oxide (In203). As the reflective material, various embodiments use lithium (Li), calcium (Ca), lithium fluoride/calcium (LiF/Ca), lithium fluoride/aluminum (LiF/Al), aluminum (Al), silver (Ag), magnesium (Mg) or gold (Au).

In some embodiments, the organic emission layer is made of low molecular weight material or high molecular weight material. Such an organic emission layer may be formed of a multilayer structure including a hole injection layer, a hole transporting layer, a emission layer, an electron transporting layer and an electron injection layer. That is, the hole injection layer is formed on the pixel electrode (i.e., the positive electrode), and the hole transporting layer, the emission layer, the electron transporting layer and the electron injection layer are sequentially stacked on the hole injection layer.

FIG. 6D corresponds to the step S104 of FIG. 5, providing a cover plate 212.

FIG. 6E corresponds to the step S105 of FIG. 5, attaching a polarizer 206 on the cover plate 212. The polarizer 206 includes a linear polarizing layer 202 and a phase retardation plate 204. Wherein, the phase retardation plate 204 is a quarter wavelength plate, and a crossing angle between the optic axis of the phase retardation plate 204 and the polarizing axis of the linear polarizing film 202 is about 45 degrees. The linear polarizing film 202 is formed of polyvinyl alcohol based material. FIG. 6F corresponds to step S106 of FIG. 5, and the cover plate 212 attached with the polarizer 206 is packaged onto the organic light emitting diode unit 208, and the polarizer 206 is positioned between the organic light emitting diode unit 208 and the cover plate 212.

Compared with a typical organic light emitting display device, the thickness of the organic light emitting display device provided by the present disclosure may be reduced by 0.15mm to 0.3mm. In addition, a process of attaching the polarizer onto the light emitting unit may be omitted.

Exemplary implements of the present disclosure has been illustrated and described above. It should be appreciated that the present disclosure is not limited to the disclosed implements, instead, the present disclosure intends to include all the amendments and equivalent arranges that fall within the spirit and scope of the appended claims.

What is claimed is:

1. A method of manufacturing an organic light emitting display device, comprising:
providing a substrate;
forming a thin film transistor unit on one side of the substrate;
forming an organic light emitting diode unit at a side of the thin film transistor opposite to the substrate;
providing a cover plate;
attaching a polarizer on the cover plate; and
packaging the cover plate having the attached polarizer onto the organic light emitting diode unit,
wherein the polarizer is interposed between the organic light emitting diode unit and the cover plate.

2. The method according to claim 1, wherein the polarizer comprises a linear polarizing film and a phase retardation plate, and the phase retardation plate is interposed between the linear polarizing film and the organic light emitting diode unit.

3. The method according to claim 2, wherein the phase retardation plate is a quarter wavelength plate, and an angle between the optic axis of the phase retardation plate and the polarizing axis of the linear polarizing film is about 45 degrees.

4. The method according to claim 2, wherein the linear polarizing film is formed of polyvinyl alcohol based material.

5. The method according to claim 1, wherein the substrate is made of one of the following materials:
polyethylene terephthalate;
polyisoprene;
polyethylene naphthalate;
polyethersulfone; and
polycarbonate.

6. The method according to claim 1, wherein the organic light emitting diode unit comprises:
a hole transporting layer formed on the thin film transistor unit;
an organic light emitting layer formed on the hole transporting layer; and
an electron transporting layer formed on the organic light emitting layer.

7. The method according to claim 1, wherein the cover plate is a glass cover plate.

8. An organic light emitting display device, comprising:
a substrate;
a thin film transistor unit formed on one side of the substrate;
an organic light emitting diode unit formed on a side of the thin film transistor unit opposite to the substrate;
a cover plate; and
a polarizer attached on the cover plate,
wherein the cover plate having the attached polarizer is packaged onto the organic light emitting diode unit, and the polarizer is interposed between the organic light emitting diode unit and the cover plate.

9. The organic light emitting display device according to claim 8, wherein the polarizer comprises a linear polarizing film and a phase retardation plate, and the phase retardation plate is interposed between the linear polarizing film and the organic light emitting diode unit.

10. The organic light emitting display device according to claim 9, wherein a linear polarized light passed through the linear polarizing film is circularly polarized after passing through the phase retardation plate.

11. The organic light emitting display device according to claim 10, wherein the phase retardation plate is a quarter wavelength plate, and an angle between the optic axis of the phase retardation plate and the polarizing axis of the linear polarizing film is about 45 degrees.

12. The organic light emitting display device according to claim 9, wherein the linear polarizing film is formed of polyvinyl alcohol based material.

13. The organic light emitting display device according to claim 8, wherein the substrate is made of one of the following materials:
polyethylene terephthalate;
polyisoprene;
polyethylene naphthalate;
polyethersulfone; and
polycarbonate.

14. The organic light emitting display device according to claim 8, wherein the organic light emitting diode unit comprises:
a hole transporting layer formed on the thin film transistor unit;
an organic light emitting layer formed on the hole transporting layer; and
an electron transporting layer formed on the organic light emitting layer.

15. The organic light emitting display device according to claim 8, wherein the cover plate is a glass cover plate.
